(19) United States
(12) Patent Application Publication
(10) Pub. No.: US 2009/0184393 A1
(43) Pub. Date: Jul. 23, 2009

(54) MEMORY CAPACITOR AND MANUFACTURING METHOD THEREOF

(75) Inventors: Wen-Hwa Chen, Hsinchu City (TW); Hsien-Chie Cheng, Hsinchu City (TW); Yun-Chiao Chen, Taichung County (TW); Su-Tsai Lu, Miaoli County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/195,412

(22) Filed: Aug. 20, 2008

(30) Foreign Application Priority Data
Jan. 21, 2008 (TW) 97102191

(51) Int. Cl. H01L 21/02; H01L 29/92

(52) U.S. Cl. 257/532; 438/381; 257/E29.343; 257/E21.008

(57) ABSTRACT

The structure strength of a memory capacitor is reduced as the height of the memory capacitor is increased, which results in collapse and a short circuit. This invention provides a capacitor with a special reinforced structure outside, wherein the reinforced structure extends upward from the bottom of the lower electrode of the capacitor to a height, thus reducing the deformation caused by the process loading and supplying sufficient capacitance. In addition, the height of the reinforced structure is adaptable to requirement. Thereby, even when the capacitors are connected with one another because the capacitors collapse, the capacitors are prevented from malfunction. Moreover, the reinforced structures can be connected to one another or not, and thus the structure strength of the capacitor arrays is increased. Besides, the process is simplified and the cost is also reduced.

### CROSS-REFERENCE TO RELATED APPLICATION

This application claims the priority benefit of Taiwan application serial no. 97102191, filed on Jan. 21, 2008. The entirety of the above-mentioned patent application is hereby incorporated by reference herein and made a part of specification.

### BACKGROUND OF THE INVENTION

1. Field of the Invention

The present invention relates to a semiconductor device and a manufacturing method thereof. More particularly, the present invention relates to a memory capacitor and a manufacturing method thereof.

2. Description of Related Art

With the recent developments in the field of electronics, a large number of electronic products termed as ‘3C’ products such as computers, communication and consumer electronic products are being widely produced. These electronic products require a variety of semiconductor components, which have different functions. Therefore, an application specific integrated circuit (ASIC) has been developed for manufacturing and integrating semiconductor components in accordance with their different requirements. For example, a mixed mode circuit (MMC) is a type of ASIC, wherein a capacitor and a complementary metal oxide semiconductor (CMOS) device are integrated.

For example, semiconductor memory devices generally include the capacitor or a transistor for storing and reading data or information, such as a dynamic random access memory (DRAM) component, a static random access memory (SRAM) component, and etc. Due to the rapid increase in the memory space needed to operate computer software, the required number and capacitance of the capacitors are also increased. To satisfy this growing demand for capacitors, some basic modification is required to be made to the existing techniques for manufacturing the semiconductor device.

Regarding the DRAM, the DRAM industry has a high amount and a high value of the production in the semiconductor industry. In order to occupy more market shares, companies compete with one another to develop advanced techniques for manufacturing the DRAM.

In order to increase the integration of the DRAM, the components are increasingly miniaturized, so that the cross-section per unit capacitor and the distance between the capacitors becomes smaller and smaller. In the limited space, the capacitor must provide sufficient capacitance to maintain signal intensity. Therefore, the correlation between the capacitance, and the design and the arrangement of the memory capacitor is emphasized when designing the DRAM. In addition to that, the process is simplified to increase the production yield and reduce the cost.

The conventional memory capacitor is a plannar capacitor. Along with the increase in the requirement of the memory capacitor, the structure is developed into a 3-dimensional structure to contain more memory units per unit area, so that a trench capacitor and a stack capacitor are designed. In the trench capacitor, a trench is dug, from a surface of the wafer, to serve as a capacitor, such that the integration of the memory capacitor is increased and the capacitance is sufficient. However, because etching efficiency is reduced by a high aspect ratio of the trench capacitor, the process encounters physical limits. As regards the stack capacitor, the capacitors are stacked over the surface of a chip in order to increase the capacitance. The advantage is that it is easy to expand the capacitance and to overcome processing problems.

However, the stacked capacitors have problems required to be solved. In order to have a large number of the capacitors, a design rule of a capacitor layout is advanced from 8F² to 6F², and thereby results in a 20% deduction of the chip size and a 20% deduction of the area of each of the net dies. However, it also causes the distance between the capacitors to decrease, and a 15% deduction of the cross-sectional area of the capacitors. In order to maintain the capacitance, in addition to changing the shape of the capacitors to increase the surface of the capacitor, one method is to utilize a dielectric film with a high dielectric constant. However, when a dielectric constant is higher, a leakage current problem is getting serious, so that the process has to be improved. Therefore, increasing the height of the capacitor has become a widely adopted strategy.

In addition, in order to increase the capacitance, a cylindrical capacitor having larger inner and outer surfaces than a conventional capacitor is adopted instead of a cup capacitor having a firm structure, but a twin bit failure may occur because the structure strength is weakened. For example, in a 90 nm process, the memory capacitors are unstable, so they may contact with one another. There are two ways to solve the problem. One is to actively design the distance between the memory capacitors to avoid the contact therebetween. The other is to passively add a support structure between the memory capacitors in the process to prevent collapse of the memory capacitors.

The support structure is set forth in quite some US patents or US patent applications. In U.S. Pat. No. 7,126,180, a ring-shaped/bowl-shaped stabilizer is disposed outside the capacitor and has a shape of a trapezoid having a top width larger than a bottom width. The ring-shaped/bowl-shaped stabilizer is fixed near a top of the lower electrode plate, and the stabilizers are connected, along a diagonal direction, between the capacitors. In US patent application no. 2005/0161720, a stabilizer having a protrusion is disposed outside the memory capacitor and is connected to an adjacent connection part to form an H shape. Furthermore, a ring-shaped stabilizer is disclosed in US patent application no. US2005/0253179, wherein the ring-shaped stabilizer is inserted into a ring-shaped trench and is vertical to a lower electrode plate. Stabilizers disclosed in U.S. Pat. No. 7,247,537 are disposed near a top of a lower electrode plate, and are connected to one another. An upper part of a stabilizer disclosed in US2005/0040448 is bended inwardly. A support structure disclosed in US2006/0211178 is a disc surrounding a lower electrode plate, and there are connection parts between the lower electrode plates. In the prior arts, most of the reinforced structures are passive support structure, and it requires the connection parts to connect the support structure to one another.

### SUMMARY OF THE INVENTION

The present invention is directed to a memory capacitor having a reinforced structure disposed outside the bottom of the lower electrode to effectively improve the structure strength of the memory capacitor and to prevent the memory capacitor from malfunctioning due to collapse of the memory capacitor.

The present invention provides a memory capacitor including a lower electrode, a dielectric layer, an upper electrode and a reinforced structure. The dielectric layer is disposed on the lower electrode, and the upper electrode is disposed on the dielectric layer. The reinforced structure is disposed at an outer wall of the lower electrode and extending upward from the bottom of the lower electrode to a height.

According to the present invention, in the memory capacitor, the reinforced structure is disposed outside the lower electrode and supports the capacitor from the bottom upward. Therefore, deformation due to process overloading can be reduced, malfunction of the memory capacitor due to collapse is prevented, and capacitance of the memory capacitor can be increased under the circumstance that a layout area is not affected. Even if lateral displacement of the memory capacitor is too large, the electrode can be separated from the adjacent electrode with the reinforced structure. Moreover, by using the manufacturing method for the memory capacitor, the process is simplified, and the process cost is reduced.

The present invention provides a manufacturing method for a memory capacitor. First, a first mold layer is formed on the substrate. Next, a reinforced structure is formed in the first mold layer, wherein the reinforced structure penetrates the first mold layer from the bottom to the top. Then, a second mold layer is formed on the substrate, and a contact opening is formed in the second mold layer and the first mold layer, wherein the contact opening exposes an inner sidewall of the reinforced structure and a conductive portion on a surface of the substrate. After that, a lower electrode is formed on an inner sidewall of the contact opening and the surface of the conductive portion. Thereafter, a dielectric layer and an upper electrode are sequentially formed on the substrate to cover the lower electrode and the reinforced structure.

According to the present invention, in the manufacturing method for the memory capacitor, the reinforced structure is formed outside the bottom of the lower electrode by using the simple flow, so that the structure strength of the memory capacitor is improved, the collapse of the memory capacitor is prevented.

In order to make the aforementioned and other objects, features and advantages of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. FIGS. 1A to 1G are top views illustrating a memory capacitor and a process thereof according to one embodiment of the present invention.

FIGS. 2A to 2G are cross-sectional views for illustrating the memory capacitor and the process flow along a line I-I′ of FIGS. 1A to 1G.

FIGS. 1B-1, 1B-2 and 1B-3 are top views illustrating memory capacitors and process flows thereof according to various embodiments of the present invention.

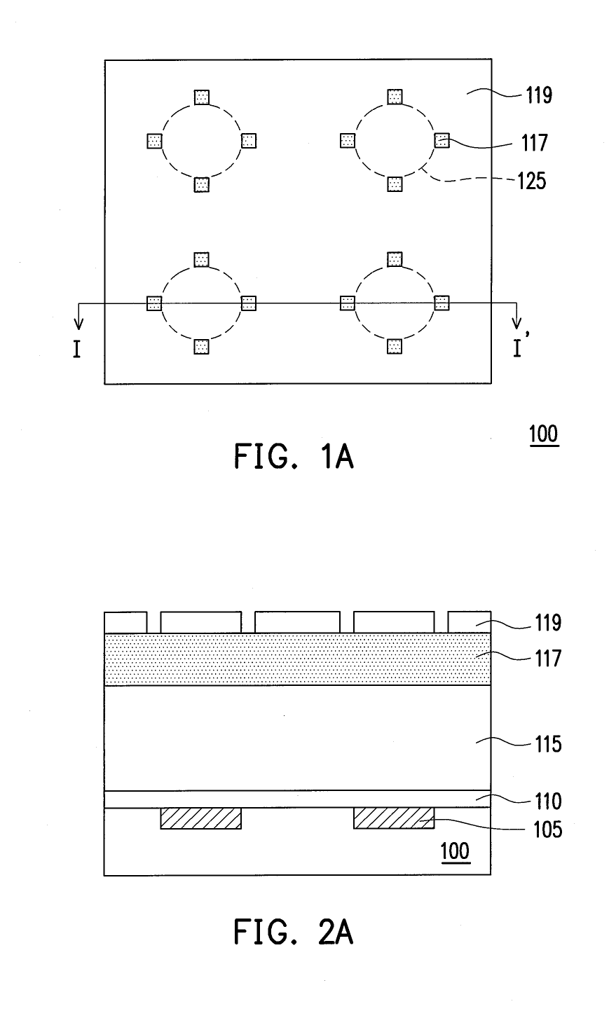

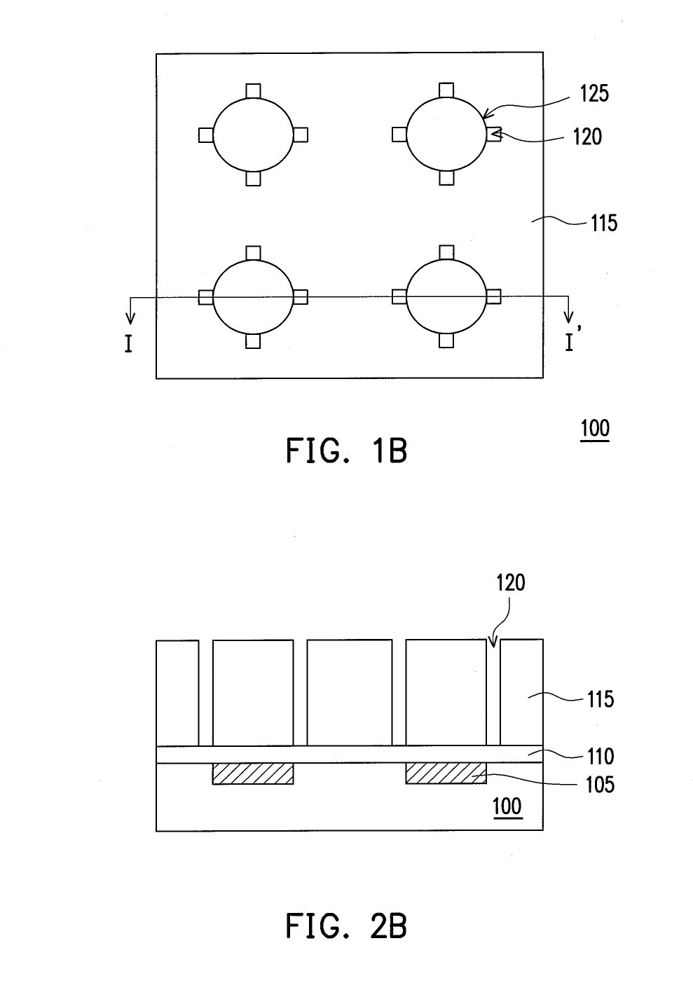

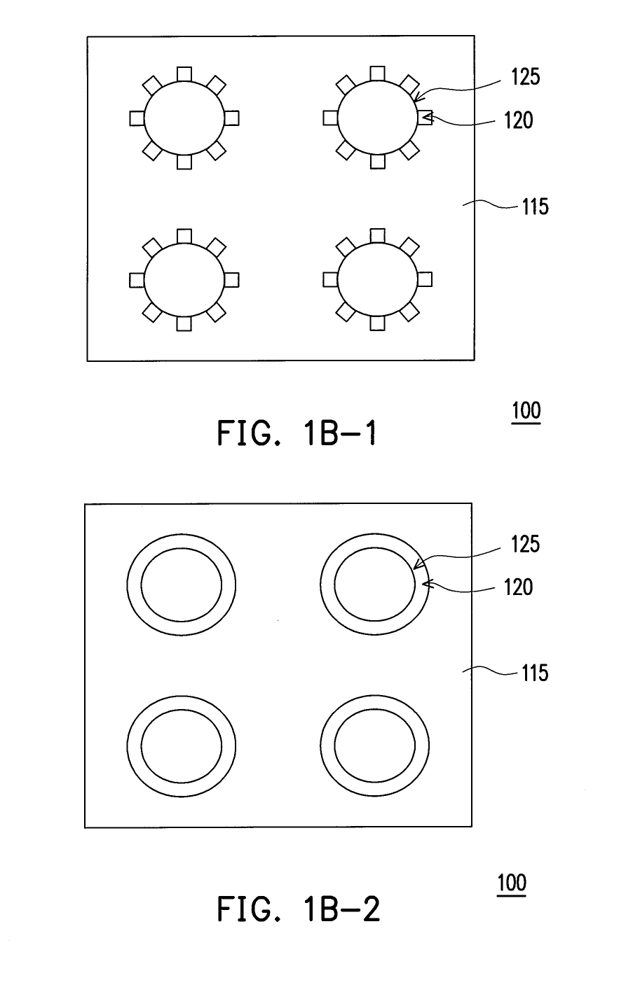

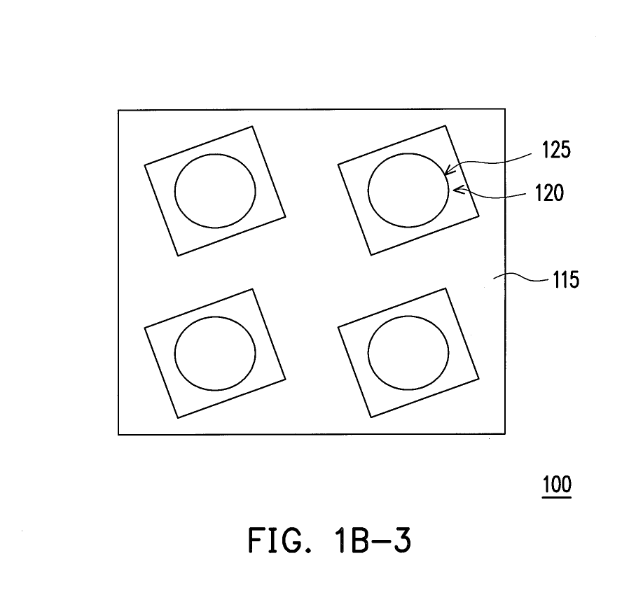

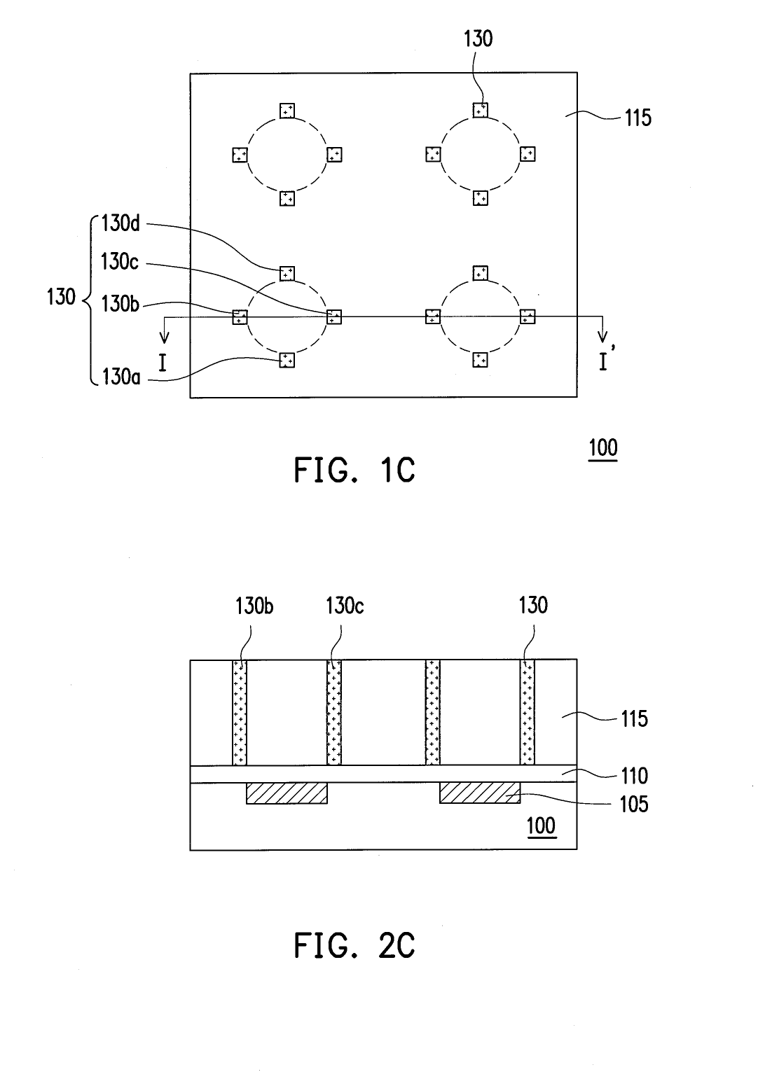

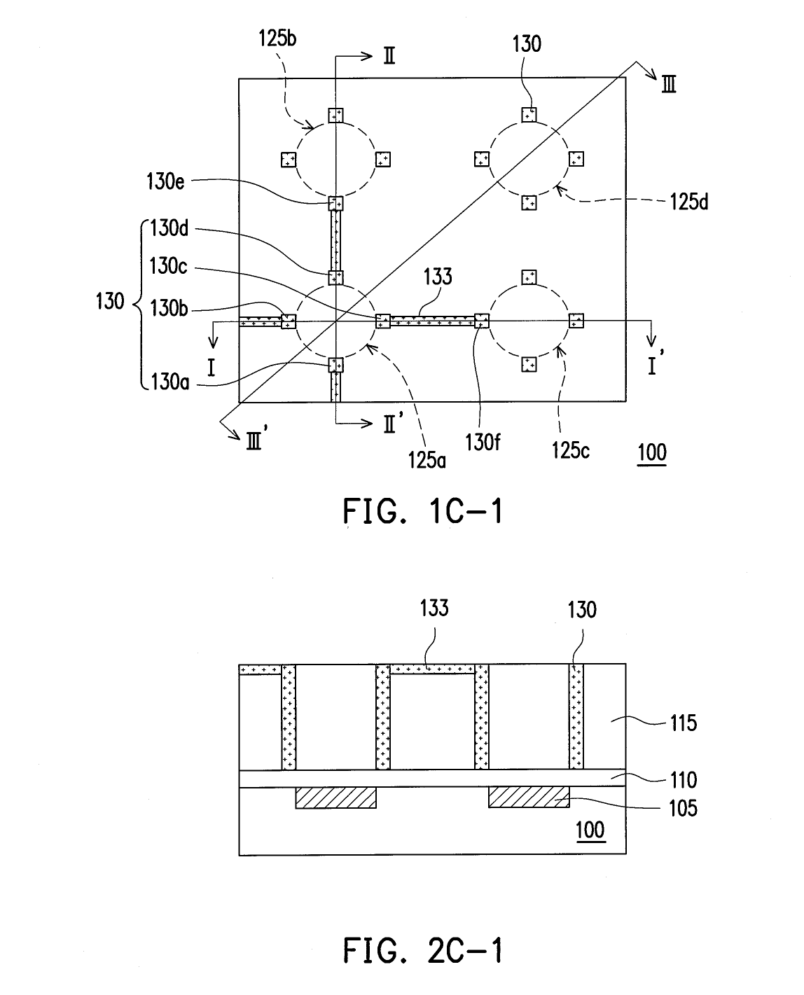

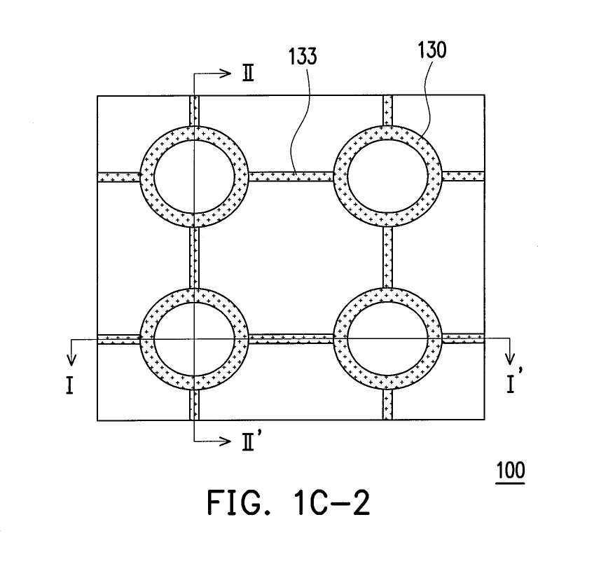

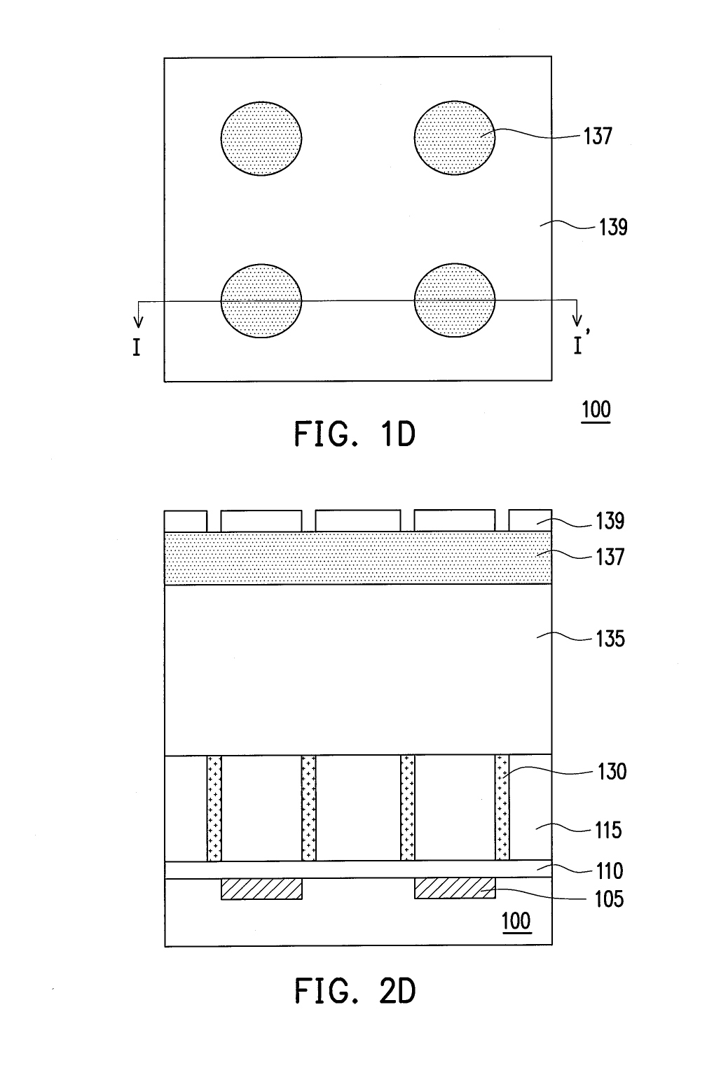

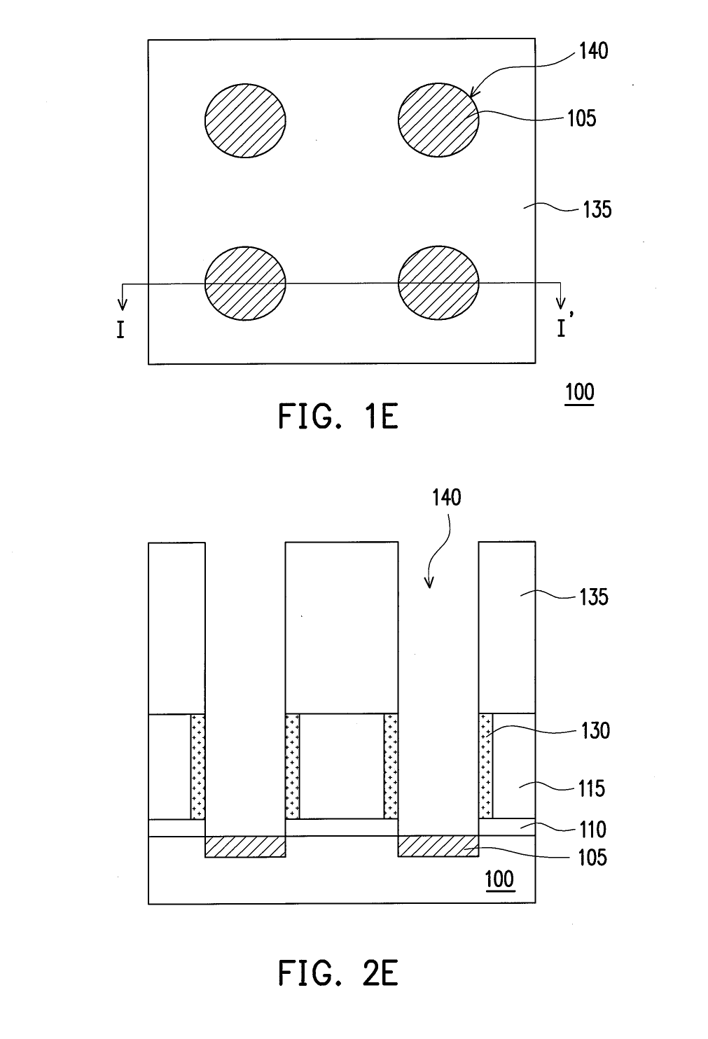

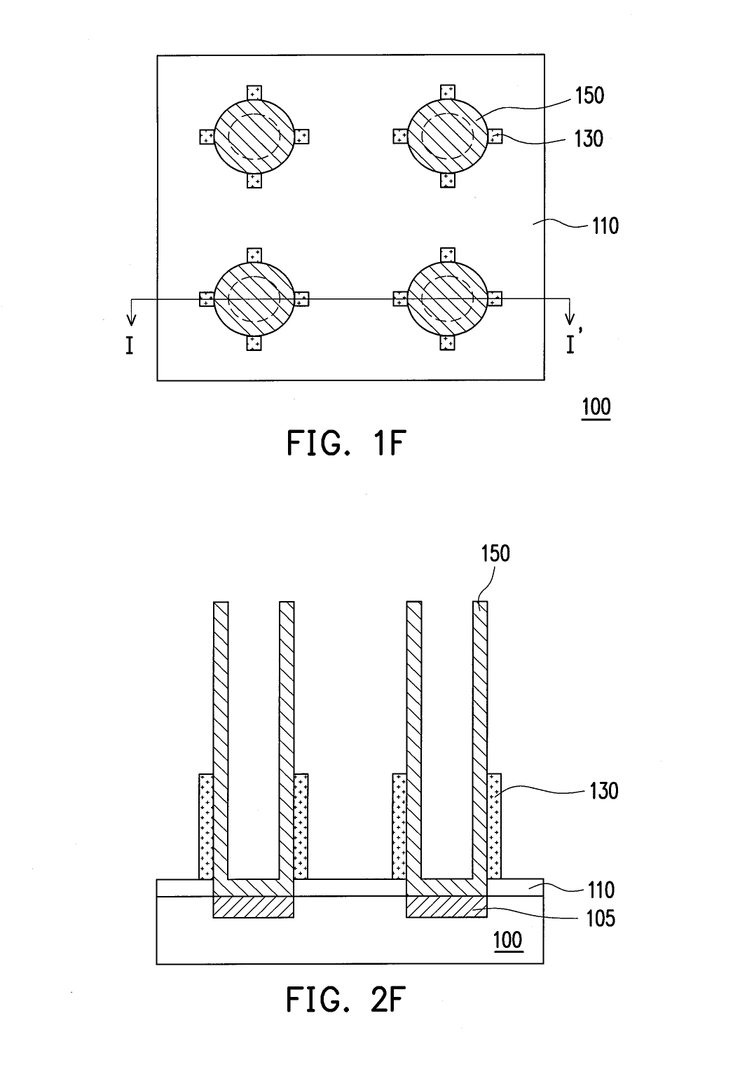

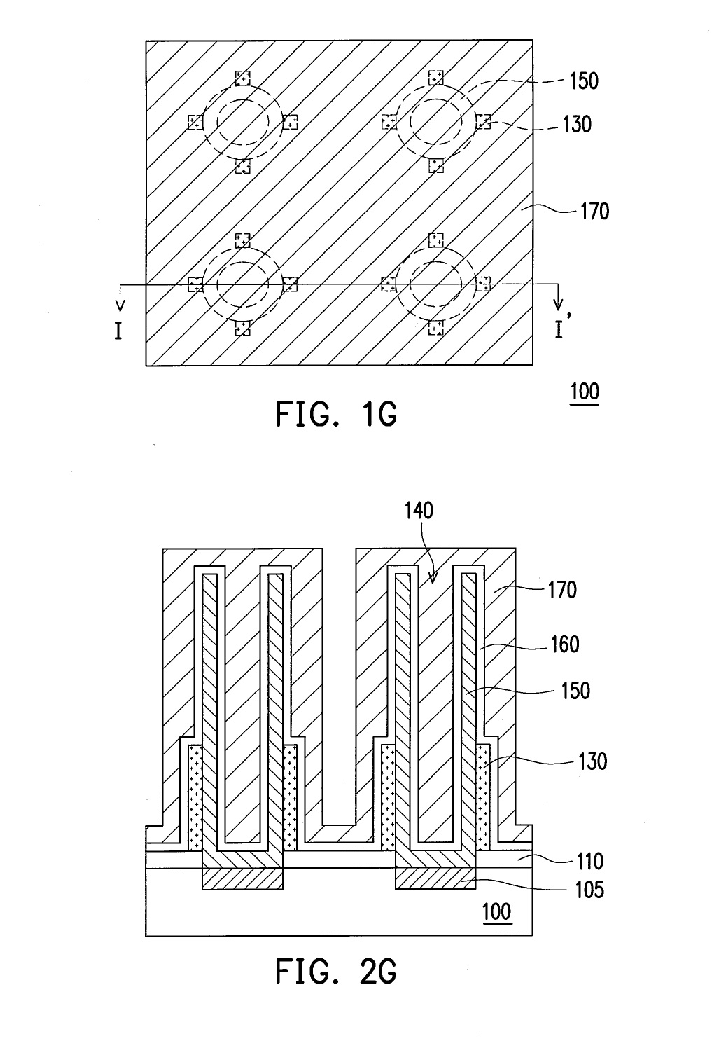

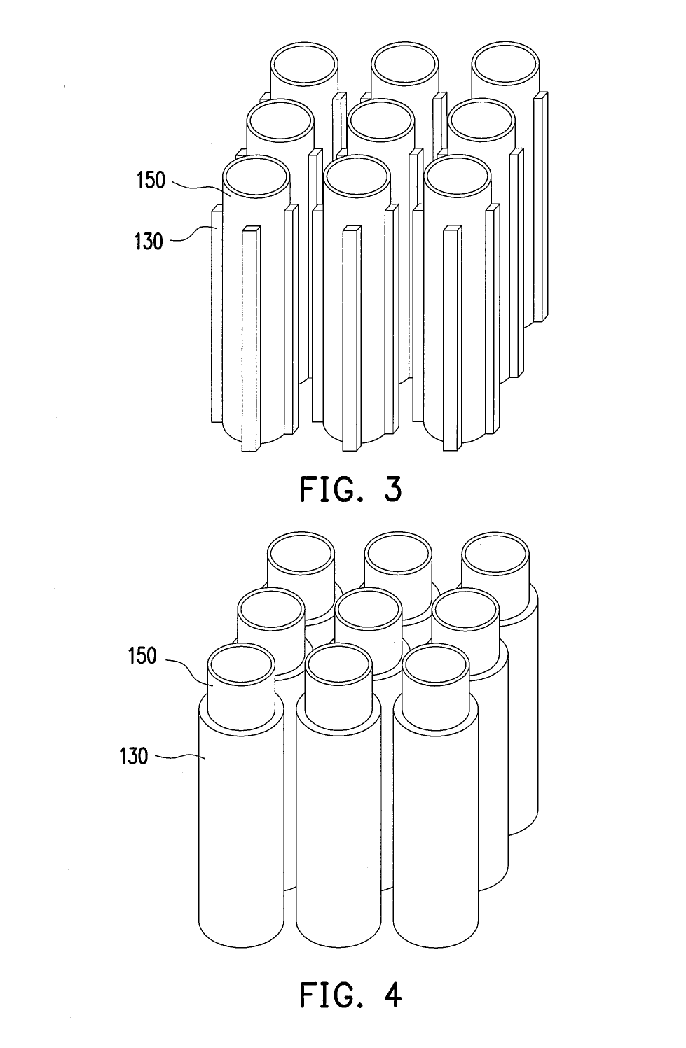

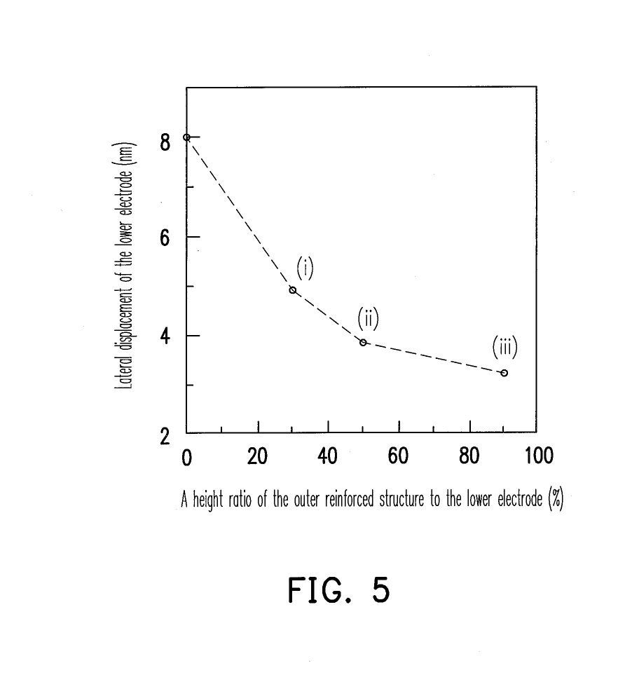

FIGS. 1C-1 and 1C-2 are top views of memory capacitors according to various embodiments of the present invention.

FIG. 2C-1 is a cross-sectional view illustrating the memory capacitor of FIG. 1C-1 along the line I-I′.

FIG. 3 is a side view of a memory capacitor according to one embodiment of the present invention.

FIG. 4 is a side view of a memory capacitor according to another embodiment of the present invention.

FIG. 5 is a diagram illustrating a relationship between lateral displacement of the lower electrode and a height ratio of a reinforced structure to a lower electrode, wherein the relationship is analyzed by using ANSYS limited unit software.

### DESCRIPTION OF EMBODIMENTS

FIGS. 1A to 1G are top views illustrating a memory capacitor and a process flow thereof according to one embodiment of the present invention. FIGS. 2A to 2G are cross-sectional views for illustrating the memory capacitor and the process flow thereof along a line I-I′ of FIGS. 1A to 1G.

Referring to FIGS. 1A and 2A, the process flow for manufacturing the memory capacitor includes providing a substrate 100 at first. A conductive portion 105, for example, is disposed on a surface of the substrate 100 is. The substrate includes a wafer with film layers and components formed on the wafer. The components include, for example, a dynamic random access memory (DRAM), a static random access memory (SRAM), a non-volatile memory, a metal-oxide-semiconductor (MOS) transistor, or etc. An isolation layer 110 can be formed on the substrate 100 to prevent an electrical connection between the components over the isolation layer 110 and the components beneath the isolation layer 110. The material of the isolation layer 110 includes, for example, silicon oxide, silicon nitride, or other insulating materials. The material of the conductive portion 105 includes, for example, doped polysilicon, metals, or other conductive materials for connecting the subsequently formed memory capacitor with the components thereunder.

A mold layer 115 is formed on the substrate 100. The material of the mold layer 115 includes, for example, boron phosphorous silicon glass (BPSG), phosphorous silicon glass (PSG), spin-on-glass (SOG) or undoped silicate glass (USG), tetra ethyl ortho silicate (TEOS), or silicon oxide. The mold layer 115 is formed by, for example, performing a high density plasma chemical vapor deposition (HDPCVD) process, a plasma enhanced chemical vapor deposition (PECVD) process, or other chemical vapor deposition processes.

Then, a hard mask layer 117 is formed on the mold layer 115. The material of the hard mask layer 117 includes, for example, silicon nitride, silicon oxynitride, silicon carbon, silicon carbon nitride, or etc. The hard mask layer 117 is formed by, for example, performing the chemical vapor deposition process. After that, a patterned photoresist layer 119 is formed on the hard mask layer 117. The material of the patterned photoresist layer 119 includes, for example, a positive photoresist material. The patterned photoresist layer 119 is formed by, for example, performing a spin coating process to form a photoresist material layer (not shown) on the hard mask layer 117 at first and then chemically developing patterns after an implementation of a photo-exposure process, such that the patterned photoresist layer 119 is formed.

Referring to the top view of FIG. 1A, the patterns of the hard mask layer 117, exposed by the patterned photoresist layer 119, are the patterns of the subsequently formed reinforced structure. In the embodiment of FIG. 1A, the exposed patterns of the hard mask layer 117 are four blocks arranged in a cross shape. Certainly, the patterns of the patterned photoresist layer 119 are not limited by the above-mentioned, and the patterns are decided based on the designs of the subsequently formed reinforced structure. Detailed descriptions regarding types of the reinforced structures are set forth later in the subsequent process flow for manufacturing the memory capacitor.

Thereafter, referring to FIGS. 1B and 2B, the photoresist layer 119 is used as a mask for etching the hard mask layer 117 thereunder. The hard mask layer 117 is etched by, for example, performing a dry etching process such as a reactive ion etching process. Afterwards, the patterned photoresist layer 119 is removed by performing a dry photoresist stripping process or a wet photoresist stripping process. Then, the patterned hard mask layer 117 is used as the mask for removing the mold layer 115 exposed thereunder to form an opening 120. Next, the hard mask layer 117 is removed after the opening 120 is formed. The portion of the mold layer 115 is removed by, for example, performing the dry etching process such as the reactive ion etching process. The hard mask layer 117 is removed by performing the dry etching process or the wet etching process. According to different designs of the process, the patterned photoresist layer 119 can also be removed after forming the opening 120 and before removing the hard mask layer 117.

The opening 120 penetrates the mold layer 115 to expose the isolation layer 110. The openings 120 are, for example, disposed separately around a pillar-shaped area 125 where a lower electrode is predetermined to be formed.

Referring to FIGS. 1B-1, 1B-2, 1B-3, one or more than two openings 120 are arranged separately and equidistantly around the pillar-shaped area 125, wherein the openings 120 penetrating the mold layer 115 can be substantially parallel to one another. The top view of the opening 120 can be in the shape of a square, a circle, or other geometric figures. For example, in FIG. 1B-1, eight rectangular openings are arranged separately and equidistantly around the pillar-shaped area 125. In FIG. 1B-2, there is only one opening 120, in the shape of a ring, surrounding the pillar-shaped area 125. Furthermore, an inner circumference and an outer circumference of the opening 120 can be shaped into different figures. For example, the inner circumference is in the shape of a circle and the outer circumference is in the shape of a rectangle as shown in FIG. 1B-3.

According to one embodiment of the present invention, four rectangular openings 120, as shown in FIG. 1A for example, are arranged separately and equidistantly around the pillar-shaped area 125 to form a arrangement in the cross shape. The openings are substantially parallel to one another. The above-mentioned openings 120 arranged in the cross shape are exemplified hereinafter for illustrating the subsequent process flow for manufacturing the memory capacitor.

Then, referring to FIGS. 1C and 2C, the opening 120 is filled with a dielectric material to form a reinforced structure 130. The material of the reinforced structure 130 includes, for example, silicon nitride, silicon carbon, silicon oxide, silicon oxyntride, silicon carbon nitride, aluminum oxide, or other dielectric materials. The reinforced structure 130 is formed by performing the chemical vapor deposition process. According to one embodiment of the present invention, the material of the reinforced structure 130, for example, should have a different etching selecting ratio from that of the mold layer 115, such that the reinforced structure 130 is etched slower than the mold layer 115. Thereby, it is easier to remove the mold layer 115 in the subsequent etching process, and the reinforced structure 130 remains after the mold layer 115 is removed. The opening 120 penetrates the mold layer 115 from the bottom to the top, and thus a height of the reinforced structure 130 filling up the opening 120 is adjustable by means of the height of the mold layer 115.

The reinforce structure 130 can be formed along a shortest distance between each of the pillar-shaped areas 125 (i.e. the directions of the line I-I′ and the line II-II′). Certainly, the reinforced structure 130 can be disposed along other directions to improve the structure strength. According to the present embodiment, the reinforced structure 130 is constituted by a plurality of parts 130a, 130b, 130c, 130d. The parts 130a, 130b, 130c, 130d are disposed separately around the pillar-shaped area 125, and the arrangement of the parts has the cross shape. Certainly, it is known from the above-mentioned that the opening 120 can be shaped into various patterns. Therefore, the reinforced structure 130 formed in the opening can be shaped into various patterns and is not limited to the pattern shown in FIG. 1C.

The reinforced structures 130 can be independent/separated from one another, or can be connected to one another partially or entirely. Referring to FIGS. 1C-1 and 2C-1, through a connection part 133, parts 130a, 130b, 130c and 130d around a pillar-shaped area 125a are connected to parts 130e and 130f along the shortest distance direction (i.e. along the line I-I′ and the line II-II′). The reinforced structure 130 around pillar-shaped areas 125b and 125c only use the parts 130e and 130f to be connected to the parts 130d and 130c of the adjacent reinforced structure 130. On a line III-III′, there are no connections between the reinforced structure 130 of the pillar-shaped area 125a and the reinforced structure 130 of a pillar-shaped area 125d, wherein the pillar-shaped area 125d is disposed in the diagonal direction from the pillar-shaped area 125a. In another embodiment, there can be more connections between the reinforced structures 130. As shown in FIG. 1C-2, the reinforced structures 130 disposed in the shortest distance along the line I-I′, the line II-II′, and the directions parallel thereto are connected to one another through the connections parts 133 to provide a strong support.

Regarding the reinforced structures 130 connected to one another by the connection parts 133, at the same time when the opening 120 is formed, the connection parts 133 can be formed along with the reinforced structure 130 by removing the portion of the mold layer 115 at which the connection parts 133 are predetermined to be formed. As shown in FIG. 2C-1, the connection parts 133 are disposed on an upper surface of the mold layer 115; however, the connection parts 133 are not limited to form on the upper surface of the mold layer 115 and can also be formed in the mold layer. The reinforced structure 130 can have various patterns and can be disposed along with the connection parts 133 or not. The structure strength provided by the reinforced structures 130 and the capacitance of the memory capacitor vary with different types of the reinforced structures 130. When the reinforced structure 130 occupies a larger area in the layout of the memory capacitor, the structure strength of the memory capacitor is stronger, but the capacitance of the memory capacitor is decreased. Therefore, according to the requirements of the circuit layout and the process flow, it is determined what pattern the reinforced structures 130 are in, whether to dispose connection parts 133, and how to connect.

Next, referring to FIGS. 1D and 2D, another mold layer 135 is formed on the substrate 100. The material of the mold layer 135 includes, for example, boron phosphorous silicon glass (BPSG), phosphorous silicon glass (PSG), spin-on-glass (SOG), undoped silicate glass (USG), or tetra ethyl ortho silicate (TEOS), or silicon oxide. The mold layer 135 is formed by, for example, performing the high density plasma chemical vapor deposition (HDPCVD) process, the plasma enhanced chemical vapor deposition (PECVD) process, or other chemical vapor deposition processes. Then, a hard mask layer 137 is formed on the mold layer 135. The material of the hard mask layer 137 includes, for example, silicon nitride, silicon oxynitride, silicon carbon, silicon carbon nitride, or etc. The hard mask layer 137 is formed by, for example, performing the chemical vapor deposition process. After that, a patterned photoresist layer 139 is formed on the hard mask layer 137. The material of the patterned photoresist layer 139 includes, for example, a positive photoresist material. The patterned photoresist layer 139 is formed by, for example, performing the photo-exposure process after the photoresist material layer is formed by performing the spin coating process.

Thereafter, referring to FIGS. 1E and 2E, the photoresist layer 139 is used as the mask for removing the hard mask layer 137 thereunder. After removing the patterned photoresist layer 139, the hard mask layer 137 is used as the mask for removing a portion of the mold layer 135, the mold layer 115, and the isolation layer 110 to form a contact opening 140. The contact opening 140 exposes an inner sidewall of the reinforced structure 130 and the conductive portion 105 on the surface of the substrate 100. The mold layer 135, the mold layer 115, and the isolation layer 110 are partially removed by, for example, performing the dry etching process. After forming the contact opening 140, the hard mask layer 137 is removed by performing the dry etching process or the wet etching process.

Then, referring to FIGS. 1F and 2F, a conformal conductive material layer (not shown) is formed on the mold layer 135 and is filled into the contact opening 140. After that, by removing the conductive material layer on the mold layer 135 and outside the contact opening 140, a lower electrode 150 is formed on an inner sidewall of the contact opening 140 and on a surface of the conductive portion 105. The material of the lower electrode 150 includes, for example, polysilicon, doped polysilicon, titanium/titanium nitride, copper, or other conductive materials. The lower electrode 150 has, for example, a cup shape, namely, a hollow cylindrical shape having a bottom. In the embodiment, according to the top view shown in FIG. 1F, the lower electrode 150 has a ring-shaped cross-section. However, the pattern of the lower electrode 150 is not limited to the above-mentioned, and can be an oval-shaped ring, a rectangular, or other figures. Certainly, the lower electrode 150 can be a pillar-shaped structure, and not limited to the hollow pillar-shaped structures shown in FIGS. 1F and 2F. The height of the lower electrode 150 is adjustable by means of the height of the mold layer 115 and the height of the mold layer 135.

After that, the mold layers 135 and 115 are removed by performing the dry etching process or the wet etching process. The height of the reinforced structure 130 is, for example, more than 30% of the height of the lower electrode 150 in order to support the lower electrode 150. According to one embodiment of the present invention, the height of the reinforced structure 130 can be more than one second of the height of the lower electrode in order to support the lower electrode 150 firmly. The height of the reinforced structure 130 can be designed according to the thickness and the height of the memory capacitor (esp. the lower electrode 150). By designing/adjusting the height of the reinforced structure 130, the memory capacitor is allowed to have lateral displacement. Even if the memory capacitor collapses because the lateral displacement of the memory capacitor is too large, by means of the isolation of the memory capacitor, the capacitors are prevented from malfunction caused by electrical connection.

After the lower electrode 150 and the reinforced structures 130 are formed, referring to the side view as shown in FIG. 3, the reinforced structures 130 are disposed at the outer wall 150 of the lower electrode and extend from the bottom upward, and the reinforced structures 130 are disposed separately at the outer wall of the lower electrode 150 and arranged in the cross shape. If the reinforced structure 130 is in the ring shape, the reinforced structure 130 surrounds the outer wall of the lower electrode 150, as shown in FIG. 4.

After that, referring to FIGS. 1G and 2G, a dielectric layer 160 is formed on the exposed surface of the substrate 100, and covers the isolation layer 110, the reinforced structure 130 and the lower electrode 150. The material of the dielectric layer 160 comprises, for example, silicon oxide, and may be formed by performing, for example, the chemical vapor deposition process. Then, an upper electrode 170 is formed on the substrate 100 by performing the chemical vapor deposition process to deposit the conductive material on the substrate 100. The conductive material may be polysilicon, doped polysilicon, or other conductive materials containing metals such as titanium/titanium nitride, copper, tungsten, and etc. For example, in the present embodiment, the conductive material entirely fills up the contact opening 140, so that the conductive material covers the dielectric layer 160, the lower electrode 150 and the reinforced structure 130, and entirely fills up the hollow space in the lower electrode 150.

The manufacture of the memory capacitor is completed after the upper electrode 170 is formed. The dielectric layer 160 is used as a capacitor dielectric layer in the memory capacitor, and is sandwiched in between the lower electrode 150 and the upper electrode 170. The capacitance of the memory capacitor is sufficient by using the inner surface and the outer surface of the capacitor, thereby solving the capacitance problem due to the miniaturized components.

Because the reinforced structure 130 extends upward from the bottom of the lower electrode 150, the structure strength of the memory capacitor is increased and the possibility of the lateral displacement of the memory structure is reduced. Thereby, it is less likely for the memory capacitor to collapse. Because the design in the height of the reinforced structure 130, the reinforced structures 130 can become the baffle plates between the lower electrodes 150. Thereby, the memory capacitor is allowed to have small lateral displacement. Therefore, even if the memory capacitor collapses because the lateral displacement is too large, the short circuit of the memory capacitor is avoided.

As regards the memory capacitor of the present invention, the characteristics and the materials are described above, and therefore the detailed descriptions are omitted.

Hereinafter, the structure strength of the lower electrode 150 is analyzed by using ANSYS. A lateral force is applied to a top of the lower electrode 150 for observing the relationship between the height ratio of the outer reinforced structure 130 to the lower electrode 150 and the lateral displacement of the lower electrode.

Referring to FIG. 5, when there is no outer reinforced structure and the lateral force is constant, the lateral displacement of the lower electrode 150 is 8 nm. In addition, it can be known from FIG. 5 that the lateral displacement of the lower electrode 150 is reduced as the height ratio of the reinforced structure 130 to the lower electrode 150 is increased. When the height of the reinforced structure 130 is 30% of the height of the lower electrode 150, the lateral displacement of the lower electrode 150 is less than 5 nm. When the height of the reinforced structure 130 is 50% of the height of the lower electrode, the lateral displacement of the lower electrode is decreased to less than 4 nm. When the height of the reinforced structure 130 is 90% of the height of the lower electrode, the lateral displacement of the lower electrode 150 is close to 3 nm. When the height ratios of the reinforced structure 130 are (i)-(ii) and (iii), the lateral displacement of the lower electrode 150 is respectively (i) 39%-(ii) 52% and (iii) 60%. When the reinforced structure 130 is higher and occupies a larger proportion of the height of the lower electrode 150, the lateral displacement of the lower electrode is smaller.

In other words, it can be known from the above analysis, the reinforced structure can reduce the possibility that the memory capacitors contact one another. Even when the lateral displacement of the memory capacitor is too large, the outer reinforced structure can be used as the baffle plate to prevent the electrodes from contacting one another. Therefore, the short circuit between capacitors can be avoided.

In summary, by utilizing the reinforced structure disposed at the outer wall of the lower electrode and extending upward from the bottom of the lower electrode, the structure strength of the memory capacitor and the capacitor array is improved, so that the memory capacitor is prevented from malfunction due to the collapse of the memory capacitor. Furthermore, the process is simple and thus the cost is reduced.

Moreover, the height of the reinforced structure is adjustable according to the thickness and the height of the memory capacitor, and the lateral displacement of the memory capacitor is allowed to a certain degree. Therefore, even if the memory capacitor collapses, the memory capacitor is prevented from the malfunction due to the isolation provided by the reinforced structure.

In addition, the reinforced structures can be connected or not connected to one another, and thus the structure strength of the capacitor array can be improved while the capacitance is also considered. Therefore, suitable memory structure can be provided to solve the problems caused when the memory capacitor is increasingly miniaturized.

Although the present invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed description.

What is claimed is:

1. A memory capacitor, comprising:
a lower electrode;
a dielectric layer disposed on the lower electrode;
an upper electrode disposed on the dielectric layer; and
a reinforced structure disposed at an outer wall of the lower electrode and extending upward from the bottom of the lower electrode to a height.

2. The memory capacitor according to claim 1, wherein the reinforced structure surrounds the lower electrode.

3. The memory capacitor according to claim 1, wherein the reinforced structure comprises a plurality of parts disposed separately at the outer wall of the lower electrode.

4. The memory capacitor according to claim 2, wherein the parts are arranged separately and equidistantly at the outer wall of the lower electrode.

5. The memory capacitor according to claim 1, wherein the reinforced structure can be connected with an adjacent reinforced structure or not.

6. The memory capacitor according to claim 1, wherein the height of the reinforced structure is more than 30% of the height of the lower electrode.

7. The memory capacitor according to claim 1, wherein the lower electrode has a cylindrical shape.

8. The memory capacitor according to claim 7, wherein the reinforced structure is a ring-shaped structure surrounding the lower electrode.

9. The memory capacitor according to claim 1, wherein a material of the reinforced structure comprises silicon nitride, silicon oxide, silicon oxynitride, or aluminum oxide.

10. The memory capacitor according to claim 1, wherein a material of the lower electrode and the upper electrode comprises doped polysilicon.

11. The memory capacitor according to claim 1, wherein the memory capacitor is suitable for a random access memory.

12. A manufacturing method for a memory capacitor, comprising:
forming a first mold layer on a substrate;
forming a reinforced structure in the first mold layer, the reinforced structure penetrating the first mold layer from the bottom to the top;
forming a second mold layer on the substrate;
forming a contact opening in the second mold layer and the first mold layer, the contact opening exposing an inner sidewall of the reinforced structure and a conductive portion on a surface of the substrate;
forming a lower electrode on an inner sidewall of the contact opening and a surface of the conductive portion; and
sequentially forming a dielectric layer and an upper electrode on the substrate to cover the lower electrode and the reinforced structure.

13. The manufacturing method for the memory capacitor according to claim 12, wherein a method for forming the reinforced structure comprises:
forming an opening in the first mold layer to expose the substrate below the first mold layer; and
filling the opening with a dielectric material.

14. The manufacturing method for the memory capacitor according to claim 13, wherein the opening is a ring-shaped opening surrounding a pillar-shaped area where the lower electrode is predetermined to be formed.

15. The manufacturing method for a memory capacitor according to claim 12, wherein a method for forming the reinforced structure comprises:
forming a plurality of openings penetrating the first mold layer in the first mold layer, the openings are disposed separately around a pillar-shaped area where the lower electrode is predetermined to be formed; and
filling the openings with a dielectric material to form a plurality of parts constituting the reinforced structure.

16. The manufacturing method for the memory capacitor according to claim 15, wherein the openings are arranged separately and equidistantly around the pillar-shaped area.

17. The manufacturing method for the memory capacitor according to claim 15, wherein the openings are substantially parallel to one another.

18. The manufacturing method for the memory capacitor according to claim 12, wherein the height of the reinforced structure is more than 30% of the height of the lower electrode.

19. The manufacturing method for the memory capacitor according to claim 12, wherein the lower electrode has a cylindrical shape.

20. The manufacturing method for the memory capacitor according to claim 12, wherein a material of the reinforced structure comprises silicon nitride, silicon oxide, silicon oxynitride, or aluminum oxide.

21. The manufacturing method for the memory capacitor according to claim 12, wherein a material of the first mold layer and the second mold layer includes silicon oxide.

22. The manufacturing method for the memory capacitor according to claim 12, wherein a material of the upper electrode and the lower electrode comprises doped polysilicon.

23. The manufacturing method for the memory capacitor according to claim 12, wherein the contact opening is filled up with the upper electrode.

24. The manufacturing method for the memory capacitor according to claim 12, wherein the manufacturing method is suitable for being applied to a process for manufacturing a random access memory.
